(19) United States
(12) Patent Application Publication
(10) Pub. No.: US 2015/0027883 A1
(43) Pub. Date: Jan. 29, 2015

(54) FACING TARGET SPUTTERING APPARATUS

(71) Applicant: Samsung Display Co., Ltd., Yongin-City (KR)

(72) Inventors: Hun Kim, Yongin-City (KR); Jin-Woo Park, Yongin-City (KR); Ou-Hyen Kim, Yongin-City (KR); Sun-Jin Lee, Yongin-City (KR)

(21) Appl. No.: 14/109,276

(22) Filed: Dec. 17, 2013

(30) Foreign Application Priority Data
Jul. 25, 2013 (KR) 10-2013-0088273

(51) Int. Cl. H01J 37/34

(52) U.S. Cl. CPC H01J 37/3402
USPC 204/298.16

(57) ABSTRACT

A sputtering apparatus includes a plurality of targets arranged to face each other and a magnetic unit producing magnetic field. A space between the targets is disposed on a substrate on which a deposition is being made during a sputtering process. The magnetic unit includes at least two magnet members. The space between the targets is surrounded by a space between the at least two magnet members. Each of the magnet members includes at least one first magnet and at least one second magnet separated from each other with an interval.

### CLAIM OF PRIORITY

This application claims the benefit of Korean Patent Application No. 10-2013-0088273, filed on Jul. 25, 2013, in the Korean Intellectual Property Office, the disclosure of which is incorporated herein in its entirety by reference.

### BACKGROUND OF THE INVENTION

1. Field of the Invention

One or more embodiments of the present invention relate to a sputtering apparatus, and more particularly, to a facing target sputtering apparatus in which a plurality of targets are arranged facing each other to form a deposition on a substrate.

2. Description of the Related Art

For example, thin film encapsulation used for an organic light-emitting display device (OLED) is manufactured by a deposition process such as sputtering. In other words, a thin film having a desired encapsulation function is formed on a substrate of an OLED, which is an object to be deposited, by sputtering with a prepared deposition target. Recently, among the sputtering methods, a facing target sputtering method, in which targets are arranged to face each other and discharge occurs so that high density plasma is formed to perform deposition, is widely being used.

However, during the sputtering with the facing target sputtering apparatus, electrons, which are included in the plasma and are hovering along an edge of a plasma area, are generated. When the electrons start to escape from the plasma area, instead of being confined therein, peripheral devices or the substrate that is subject to deposition may be damaged by the electrons. Such damage may badly affect both of lifespan of an apparatus and quality of a product, and thus a solution to effectively solve the problems are needed.

### SUMMARY OF THE INVENTION

One or more embodiments of the present invention include a sputtering apparatus which may prevent escape of electrons from a plasma area, reduce danger of damaging the periphery, and stabilize plasma.

Additional aspects will be set forth in part in the description which follows and, in part, will be apparent from the description, or may be learned by practice of the presented embodiments.

According to one or more embodiments of the present invention, a sputtering apparatus includes a plurality of targets arranged to face each other and a magnetic member producing a magnetic field that is to be formed in a space between the plurality of targets. The magnetic member includes a bar magnet and a cylindrical magnet.

The magnetic member may have a shape of a polygonal frame, and the bar magnet may be arranged along each side of the polygonal frame and the cylindrical magnet may be arranged at a vertex between the sides of the polygonal frame.

The magnetic member may have a shape of a rectangular frame, and the bar magnet may have arranged along each of four sides of the rectangular frame and the cylindrical magnet may have arranged at each of four vertices of the rectangular frame.

The bar magnet and the cylindrical magnet may be separated from each other with an interval.

The magnetic member may be arranged behind each of the plurality of targets facing each other.

The bar magnet and the cylindrical magnet may be arranged surrounding an outer side of each of the plurality of the targets.

The magnetic member may be arranges in a manner that when plasma is formed between the plurality of the targets, electrons included in the plasma may circulate along a peripheral region of the magnetic field produced from the magnetic member.

### BRIEF DESCRIPTION OF THE DRAWINGS

These and/or other aspects will become apparent and more readily appreciated from the following description of the embodiments, taken in conjunction with the accompanying drawings of which

FIG. 1 illustrates a structure of a deposition chamber adopting a sputtering apparatus according to an embodiment of the present invention;

FIG. 2 illustrates a detailed structure of the sputtering apparatus of FIG. 1;

FIG. 3 is a perspective view illustrating a magnetic member of the sputtering apparatus of FIG. 2;

FIG. 4 is a plan view of the magnetic member of FIG. 3; and

FIGS. 5A and 5B are views for explaining electron confinement ability in comparison between a conventional sputtering apparatus and a sputtering apparatus according to an embodiment of the present invention.

### DETAILED DESCRIPTION OF THE INVENTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

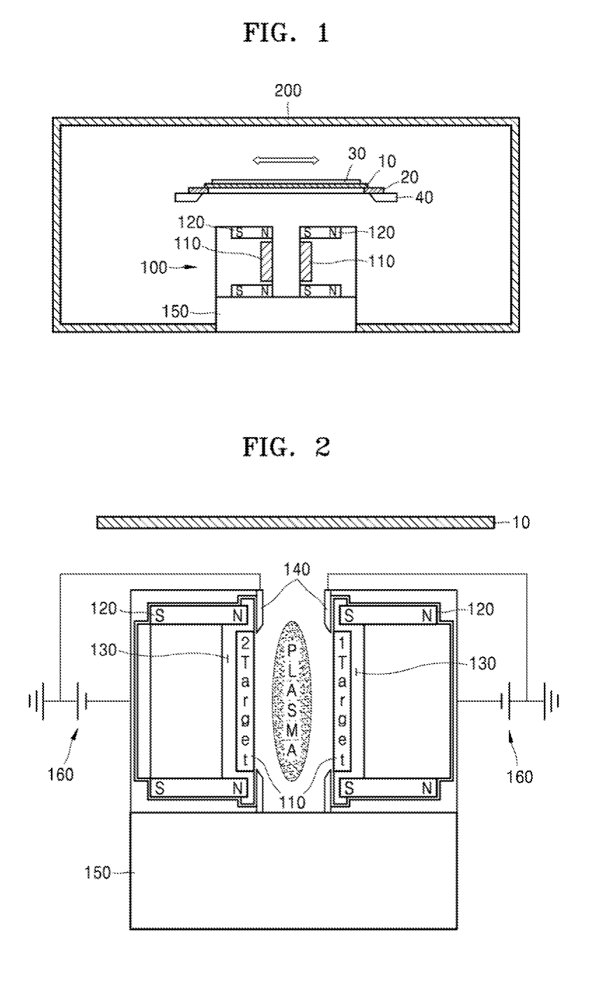

FIG. 1 illustrates a structure of a deposition chamber 200 adopting a sputtering apparatus 100 according to an embodiment of the present invention. Referring to FIG. 1, a substrate 10 interposed between a mask 20 and a pressing plate 30 is accommodated on a shuttle 40 in the deposition chamber 200 so as to reciprocate therein. The sputtering apparatus 100 for forming a desired thin film on the substrate 10 is provided under the substrate 10. Accordingly, during a sputtering process, particles are emitted from a pair of targets 110, which are provided in the sputtering apparatus 100, and adhere to the substrate 10 disposed over the mask 20, forming a thin film on the substrate 10. In other words, argon (Ar) gas is supplied into the deposition chamber 200 as a sputter gas to form plasma. In this state, a voltage is applied to the targets 110 to cause discharge so that argon ions are generated from the argon gas. As the argon ions collide against the targets 110, the particles of the targets 110 are scattered and thus the scattered particles are deposited on the substrate 10, thereby forming a thin film on the substrate 10.

The structure of the sputtering apparatus 100 for scattering the particles of the targets 110 according to the present embodiment will be described in detail.

Referring to FIG. 2, the sputtering apparatus 100 includes targets 110 arranged on a holder 150 to face each other, and magnetic members 120 arranged behind each target 110. In other words, as shown in FIG. 2, the magnetic members 120 are retreated outwardly from the surfaces of the targets 110 in order to have magnetic field produced from the magnetic members 120 completely enclose the region between the targets 120. In this configuration, the space between the targets 110 may be completely enclosed by a space between two magnet members 120. The targets 110 are deposition sources for forming a thin film on the substrate 10. The magnetic members 120 confine plasma formed between the targets 110 in a plasma area between the targets 110, as shown in FIG. 2, by the magnetic field. Accordingly, the plasma does not directly affect peripheral elements such as the substrate 10.

A shield portion 140 is arranged maintaining a fine interval with each of the targets 110 to initiate discharge. A power unit 160 applies a negative voltage (first voltage) to the targets 110 and a positive voltage (ground voltage or second voltage) to the shield portion 140 during the sputtering process. Although a direct current (DC) power is illustrated as the power of the power unit 160 in FIG. 2, a radio frequency (RF) power or a DC pulse power may be used for the power unit 160. A yoke plate 130 is provided behind the targets 100.

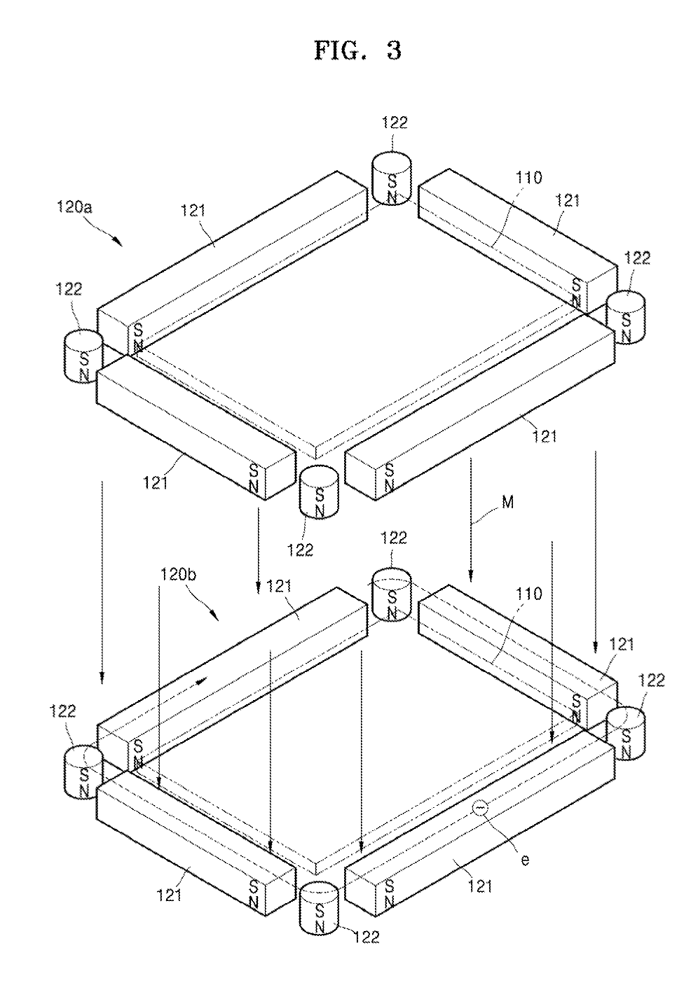

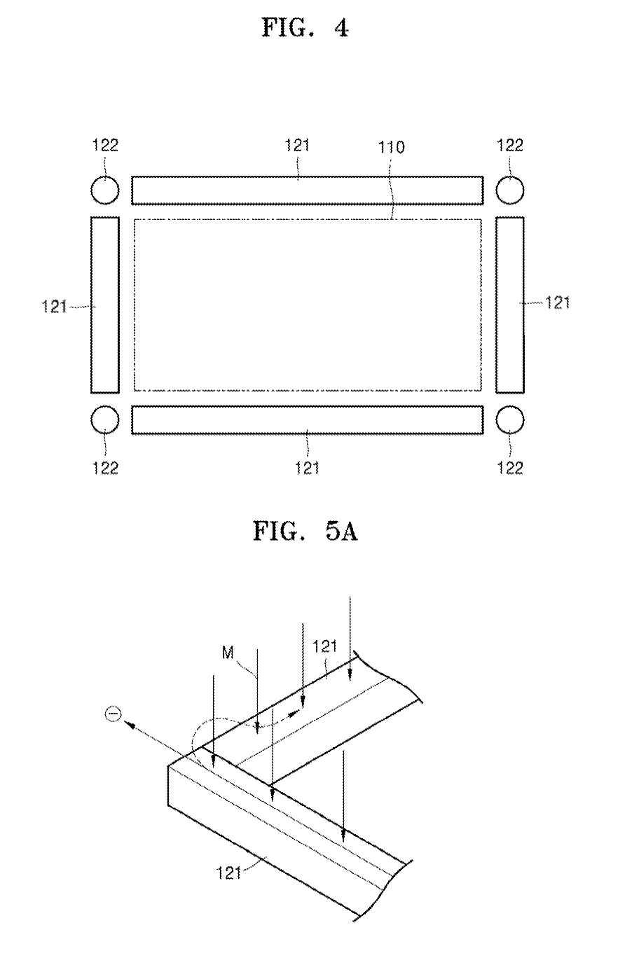

The magnetic members 120 are provided to surround the outer side of each of the targets 110. A detailed structure is illustrated in FIGS. 3 and 4. As illustrated in FIG. 3, the magnetic members 120a and 120b are arranged in a shape of a rectangular frame surrounding the outer side of each of the targets 110. The magnetic members 120a and 120b are arranged to face each other, and the space between the targets 110 is surrounded by a space between the magnet members 120a and 120b. A set of these magnetic members 120a and 120b can be referred to as a magnetic unit. Four bar magnets 121 (first magnets) are arranged along the four sides of the rectangular frame and four cylindrical magnets 122 (second magnets) are arranged at the four vertices (or corners) of the rectangular frame. Also, the present invention is not limited to the shape of a rectangle, and various polygonal shapes corresponding to the shape of each of the targets 110 may be used. For a polygonal shape, the bar magnet 121 is provided along each side and each of the cylindrical magnets 122 is provided at each vertex connecting the sides with a slight interval, and therefore, the cylindrical magnet 121 is separated from the bar magnets 121. The cylindrical magnets 122 are provided at each point where the sides are connected so that electrons rotating along the edge of a plasma area may be prevented from escaping from the plasma area.

As illustrated in FIG. 3, flat surfaces of the bar magnets 121 of the magnetic members 120a and 120b faces each other, and are arranged parallel to surfaces of the targets 110. The magnet members 120a and 120b can be referred to as first and second members, respectively. The Circular surfaces of the cylindrical magnet 122 of the magnet members 120a and 120b face each other, and are arranged parallel to surfaces of the targets 110. As shown in FIG. 3, the facing flat surfaces of the bar magnets 121 of the facing magnetic members 120a and 120b have opposite magnetic polarities, and the facing circular surfaces of the cylindrical magnets 122 of the facing magnetic members 120a and 120b have opposite magnetic polarities. When sputtering begins, plasma is formed between the two targets 110 facing each other. The plasma is confined in a magnetic field M of the magnetic member 120. Various particles such as argon gas ions or electrons exist being mixed together in the plasma. Among the various particles, some electrons e may circulate along the peripheral region of the plasma confined by the magnetic field M. Accordingly, as a force according to the Fleming's law acts on electric charges in the magnetic field M, the electrons e circulate along the rectangular frame of the magnetic member 120.

When the circulating electrons e are continuously confined in the plasma area, there will be no problem. However, as described above, if the electrons e escape from the plasma area, the substrate 10 or peripheral devices may be damaged so that lifespan of an apparatus and the substrate 10 to be manufactured into a product may be ill affected. However, when the magnetic member 120 having the above structure according to the present embodiment is employed, the electron escape phenomenon is sufficiently reduced.

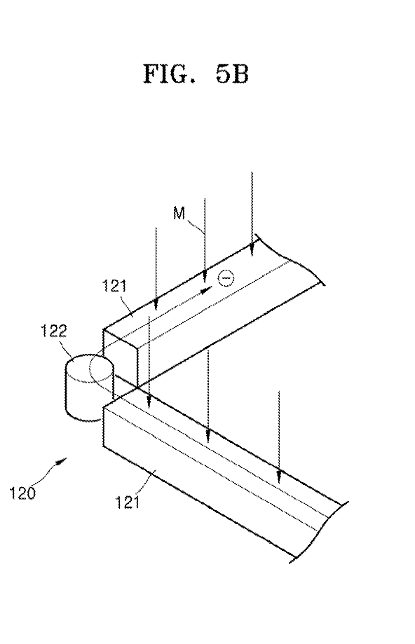

FIGS. 5A and 5B schematically illustrate a principle thereof. In a structure of a conventional magnetic member shown in FIG. 5A, as dynamic energy of the circulating electrons e increases, particularly, at a corner portion where a dynamic direction sharply changes, the electrons e may easily escape from the plasma area confined by the magnetic field M. However, when the magnetic member 120 according to the present embodiment as shown in FIG. 5B is used, since the cylindrical magnets 122 arranged at the corner portion, where the dynamic direction changes smoothly, guide the movement of the electrons e toward the next bar magnet 121 like forming rounding at the corner, a probability of the electrons e escaping from the plasma area is quite reduced. In other words, since the magnetic field M is smoothly formed like being rounded by the cylindrical magnets 122 arranged between the bar magnets 121, the electrons e circulating along the peripheral region of the magnetic field M pass through the corner portion along a smooth curvature. Accordingly, the probability of the electrons e escaping from the plasma area confined by the magnetic field M is greatly reduced.

As such, since plasma is very stably maintained during sputtering, the sputtering may be generally very stably performed. When the number of escaping electrons increases, plasma is not uniformly formed and is lopsidedly formed in an area where more number of the escaping electrons are present and thus a thin film is irregularly formed. When plasma is stably formed, a thin film deposited on the substrate 10 may be uniformly formed.

For reference, the bar magnets 121 and the cylindrical magnets 122 of the magnetic member 120 may be formed of, for example, a ferrite-based magnet, a neodymium-based magnet, a samarium cobalt-based magnet.

A deposition process using the sputtering apparatus 100 according to the present embodiment will be performed as follows.

First, as illustrated in FIG. 1, the sputtering apparatus 100 in which the targets 110 are provided in the deposition chamber 200 is prepared and the substrate 20 interposed between the mask 20 and the pressing plate 30 is provided on the shuttle 40.

When the substrate 10 and the targets 110 are prepared, argon gas is supplied to the inside of the deposition chamber 200 and sputtering is initiated while reciprocating the shuttle 40. As sputtering starts, a negative power is applied to the targets 110 and a positive voltage is applied to the shield portion 140, thereby generating discharge. Accordingly, electrons generated by the discharge collide against the argon gas and thus argon ions (Ar+ ions) are generated. Then, plasma including Ar+ ions is formed between the targets 110.

The generated plasma is maintained being confined in a space between the targets 110 facing each other by the magnetic field M of the magnetic member 120. The plasma includes various particles such as electrons, negative ions, and positive ions. The particles reciprocate between the targets 110 facing each other, maintaining high density plasma.

In this state, as the Ar+ ions in the plasma collide against the targets 110 to which a negative voltage is applied, target particles are scattered. Then, the target particles scattered from the targets 110 are deposited on the substrate 10 over the mask 20, thereby forming a thin film on the substrate 10.

While the sputtering is performed, the electrons e circulating along the peripheral region of the plasma area smoothly move along the magnetic member 120 including the bar magnets 121 and the cylindrical magnets 122, as described above. Thus, the substrate 10 or peripheral devices may be prevented from being damaged by the escaped electrons.

Thus, as described above, when deposition is performed by using the sputtering apparatus according to the present invention, escape of electrons from plasma may be prevented and stable plasma may be maintained. Thus, damage to the peripheral devices due to the escaping electrons may be reduced and the quality of a product may be stabilized.

Although only one sputtering apparatus 100 is provided in the deposition chamber 200 in the present embodiment, the number of the sputtering apparatus 100 may vary as necessary.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. A sputtering apparatus comprising:
a plurality of targets arranged to face each other; and
a magnetic member producing a magnetic field that is to be formed in a space between the plurality of targets, the magnetic member comprising a bar magnet and a cylindrical magnet.

2. The sputtering apparatus of claim 1, wherein the magnetic member has a shape of a polygonal frame, and the bar magnet is arranged along each side of the polygonal frame and the cylindrical magnet is arranged at a vertex between the sides of the polygonal frame.

3. The sputtering apparatus of claim 1, wherein the magnetic member has a shape of a rectangular frame, and the bar magnet is arranged along each of four sides of the rectangular frame and the cylindrical magnet is arranged at each of four vertices of the rectangular frame.

4. The sputtering apparatus of claim 1, wherein the bar magnet and the cylindrical magnet are separated from each other with an interval.

5. The sputtering apparatus of claim 1, wherein the magnetic member is arranged behind each of the plurality of targets facing each other.

6. The sputtering apparatus of claim 5, wherein the bar magnet and the cylindrical magnet are arranged surrounding an outer side of each of the plurality of the targets.

7. The sputtering apparatus of claim 1, wherein, the magnetic member is arranges in a manner that when plasma is formed between the plurality of the targets, electrons included in the plasma circulate along a peripheral region of the magnetic field produced from the magnetic member.

8. A sputtering apparatus comprising:
a plurality of targets arranged to face each other, a space between the targets disposed on a substrate on which a deposition is being made during a sputtering process; and
a magnetic unit producing magnetic field, the magnetic unit comprising at least two magnet members, the space between the targets being surrounded by a space between the at least two magnet members, each of the magnet members including at least one first magnet and at least one second magnet separated from each other with an interval.

9. The sputtering apparatus of claim 8, wherein the first and the second magnets of each of the magnet members are arranged in a polygonal frame, the at least one first magnet being arranged at a side of the polygonal frame, the at least one second magnet being arranged at a vertex between sides of the polygonal frame.

10. The sputtering apparatus of claim 9, wherein each of the magnet members includes a plurality of the first magnets and a plurality of the second magnets, the first magnets being disposed on sides of the polygonal frame, the second magnets being disposed at vertices between sides of the polygonal frame.

11. The sputtering apparatus of claim 9, wherein the polygonal frame is a rectangular frame.

12. The sputtering apparatus of claim 9, wherein the at least one first magnet of each of the magnet members includes a bar magnet, and the at least one second magnet of each of the magnet members includes a cylindrical magnet.

13. The sputtering apparatus of claim 12, wherein a circular surface of the cylindrical magnet is arranged parallel to a surface of one of the targets that faces a surface of another one of the targets.

14. The sputtering apparatus of claim 12, wherein a flat surface of the bar magnet is arranged parallel to a surface of one of the targets that faces a surface of another one of the targets.

15. The sputtering apparatus of claim 12, wherein a circular surface of the cylindrical magnet of one of the magnet members faces a circular surface of the cylindrical magnet of another one of the magnet members.

16. The sputtering apparatus of claim 15, wherein the circular surface of the cylindrical magnet of said one of the magnet members and the circular surface of the cylindrical magnet of said another one of the magnet members have opposite magnetic polarities.

17. The sputtering apparatus of claim 12, wherein a flat surface of the bar magnet of one of the magnet members faces a flat surface of the bar magnet of another one of the magnet members.

18. The sputtering apparatus of claim 8, wherein the at least two magnet members are arranged in a manner that the space between the targets is completely enclosed by a space between the at least two magnet members.
